(19) United States
(12) Patent Application Publication
(10) Pub. No.: US 2018/0102247 A1
(43) Pub. Date: Apr. 12, 2018

(54) SUBSTRATE PROCESSING APPARATUS AND METHOD OF MANUFACTURING SEMICONDUCTOR DEVICE

(71) Applicant: ASM IP Holding B.V., Almere (NL)

(72) Inventors: Richika KATO, Albany, NY (US); Kensuke HABA, Tokyo (JP)

(73) Assignee: ASM IP Holding B.V., Almere (NL)

(21) Appl. No.: 15/287,039

(22) Filed: Oct. 6, 2016

(51) Int. Cl. H01L 21/02; H01L 21/687; C23C 16/50; C23C 16/455; C23C 16/458; C23C 16/44

(52) U.S. Cl. CPC H01L 21/02315; H01L 21/68785; H01L 21/0228; C23C 16/4412; C23C 16/50; C23C 16/45544; C23C 16/458; H01L 21/02274

(57) ABSTRACT

A substrate processing apparatus includes a substrate support having a central first upper surface and a second upper surface surrounding the first upper surface and formed higher than the first upper surface, and an exhaust duct surrounding the substrate support, wherein a first through hole and a second through hole are formed in the substrate support, the first through hole being formed through the substrate support from the first upper surface, the second through hole connecting the first through hole and a side surface of the substrate support.

### BACKGROUND OF THE INVENTION

### Field of the Invention

The present invention relates to a substrate processing apparatus used to process a substrate such as a semiconductor wafer and to a method of manufacturing a semiconductor device by using the substrate processing apparatus.

### Background

US 2015/252479 discloses an exhaust duct surrounding a susceptor. A material gas supplied from above the susceptor spreads radially on the susceptor, enters the exhaust duct and is discharged to the outside.

In a substrate processing apparatus for performing, for example, a plasma-enhanced CVD (PECVD) process or a plasma-enhanced atomic layer deposition (PEALD) process, it is preferable to inhibit film forming on the lower surface of a substrate while performing film forming on the upper surface of the substrate. If a film is formed on the lower surface of the substrate, a reduction in yield occurs and some other apparatus in the semiconductor device production lines are contaminated due to the film on the lower surface of the substrate. There is, therefore, a demand for preventing film forming on the lower surface of the substrate.

### SUMMARY OF THE INVENTION

In view of the above-described problem, an object of the present invention is to provide a substrate processing apparatus capable of preventing film forming on the lower surface of a substrate and a method of manufacturing a semiconductor device by using the apparatus.

The features and advantages of the present invention may be summarized as follows.

According to one aspect of the present invention, a substrate processing apparatus includes a substrate support having a central first upper surface and a second upper surface surrounding the first upper surface and formed higher than the first upper surface, and an exhaust duct surrounding the substrate support, wherein a first through hole and a second through hole are formed in the substrate support, the first through hole being formed through the substrate support from the first upper surface, the second through hole connecting the first through hole and a side surface of the substrate support.

According to another aspect of the present invention, a method of manufacturing a semiconductor device includes a mount step of placing a substrate on a substrate support having a central first upper surface and a second upper surface surrounding the first upper surface and formed higher than the first upper surface, the substrate being in contact with the second upper surface, a gap being provided between the substrate and the first upper surface, and a processing step of processing the substrate by supplying a gas to the substrate from above the substrate, wherein, in the processing step, the gas in the gap moves to a side surface of the substrate support by passing through a first through hole formed through the substrate support from the first upper surface and passing through a second through hole connecting the first through holes and the side surface of the substrate support.

Other and further objects, features and advantages of the invention will appear more fully from the following description.

### BRIEF DESCRIPTION OF THE DRAWINGS

FIG.1 is a sectional view of a substrate processing apparatus;

FIG.2 is a plan view of the top plate;

FIG.3 is a sectional view of the top plate;

FIG.4 shows a substrate placed on the substrate support;

FIG.5 is diagram showing flows of the gas in the chamber;

FIG.6 is a sectional view of a substrate processing apparatus according to a comparative example; and

FIG.7 is diagram showing the thickness of film formed on the lower surface of a substrate.

### DETAILED DESCRIPTION OF THE PREFERRED EMBODIMENT

A substrate processing apparatus and a method of manufacturing a semiconductor device according to an embodiment of the present invention will be described with reference to the drawings. Components identical or corresponding to each other are assigned the same reference characters and repeated description of them is avoided in some cases.

### Embodiment

FIG. 1 is a sectional view of a substrate processing apparatus according to the embodiment. The substrate processing apparatus is provided with a chamber 10. An exhaust duct 12 is provided on the chamber 10, with an 0-ring, for example, interposed therebetween. The exhaust duct 12 is formed into an annular shape as viewed in plan. An RF plate 14 is provided above the chamber 10 and the exhaust duct 12. Slits 14a are formed in the RF plate 14. In ordinary cases, the RF plate 14 is housed in the chamber 10.

A susceptor 20 is provided in the chamber 10. A top plate 22 is provided on the susceptor 20. The top plate 22 is placed in a predetermined position on the susceptor 20 by being positioned, for example, with positioning pins. The top plate 22 has a first upper surface 22A at a center, a second upper surface 22B surrounding the first upper surface 22A and formed higher than the first upper surface 22A, and a third upper surface 22C surrounding the second upper surface 22B and formed higher than the second upper surface 22B. The thickness of the top plate 22 is, for example, about 12 mm. The top plate 22 and the susceptor 20 in combination will be referred to as a “substrate support”.

In the substrate support, first through holes 24 are formed through the substrate support from the first upper surface 22A. The first through holes 24 are holes extending through the substrate support along a z-direction. Thus, the first through holes 24 extend from the upper surface of the top plate 22 and reach a lower surface of the susceptor 20. The first through holes 24 are provided as holes through which susceptor pins 26 are passed. The susceptor pins 26 are moved vertically in the first through holes 24, thereby lifting or moving downward a substrate while supporting the substrate.

Second through holes 22a are formed in the substrate support so as to connect the first through hole 24 and a side surface of the substrate support. The second through holes 22a are holes extending along an x-direction. The second through holes 22a are generally perpendicular to the first through holes 24. The second through holes 22a are provided by forming grooves in a lower surface of the top plate 22. Thus, the second through holes 22a are holes provided between the top plate 22 and the susceptor 20.

A plurality of projections 22b extending upward are formed on the first upper surface 22A of the top plate 22. The height of each upper end of the projections 22b and the height of the second upper surface 22B are made generally equal to each other to enable a substrate to be supported by the projections 22b and the second upper surface 22B.

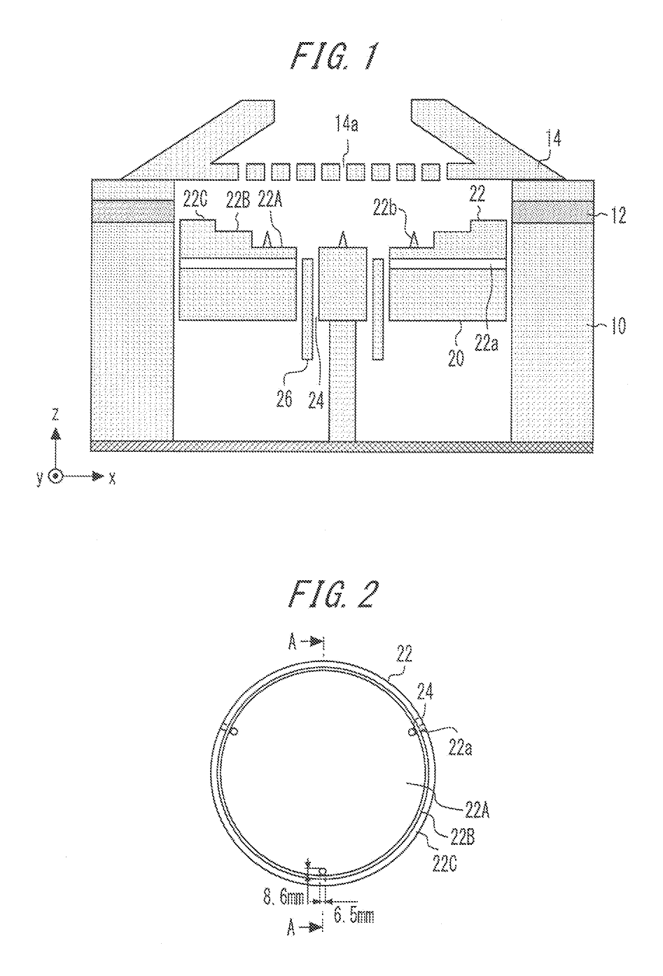

FIG. 2 is a plan view of the top plate 22. For example, several hundred projections are formed on the first upper surface 22A. However, illustration of the projections is omitted in FIG. 2. There are three first through holes 24 as seen in plan. The diameter of each first through hole 24 is, for example, 8.6 mm. In FIG. 2, the second through holes 22a are indicated by broken lines for ease of illustration. One second through hole 22a is connected to one first through hole 24. The diameter of each second through hole 22a is, for example, 6.5 mm.

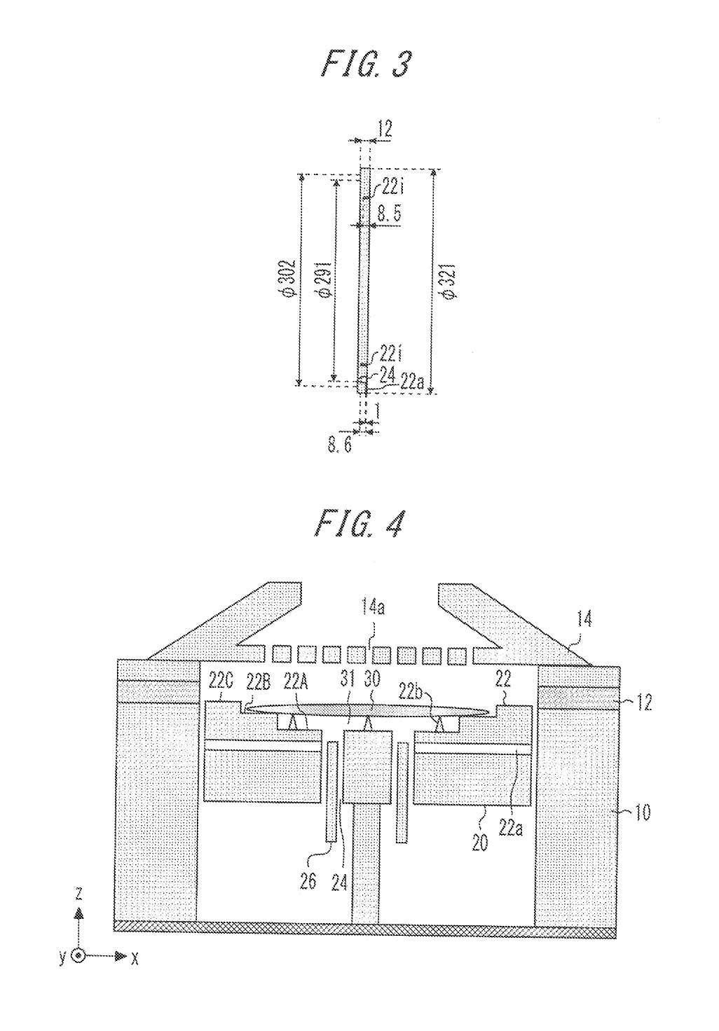

FIG. 3 is a sectional view of the top plate taken along line A-A in FIG. 2. Illustration of the step between the first upper surface 22A of the top plate 22 and the second upper surface 22B and the step between the second upper surface 22B and the third upper surface 22C are omitted. That is, the first to third upper surfaces are depicted as one flat surface in FIG. 3. Holes 22i in which positioning pins are inserted are formed in the lower surface of the top plate 22. The depth of the holes 22i is, for example, 8.5 mm. The second through holes 22a are grooves formed in the lower surface of the top plate 22 having a depth of, for example, 1 mm.

A method of manufacturing a semiconductor device by using the substrate processing apparatus according to the embodiment of the present invention will be described. First, a substrate is placed on the substrate support. FIG. 4 shows a substrate 30 placed on the substrate support. The substrate 30 is, for example, a silicon wafer. However, the substrate may be any object to be processed and is not limited to a silicon wafer. The substrate 30 is placed on the substrate support so as to be spaced apart from the first upper surface 22A by a gap 31 while being in contact with the second upper surface 22B. More specifically, a central portion of the substrate 30 and the projections 22b are brought into contact with each other to provide the gap 31 between the substrate 30 and the first upper surface 22A. Because of the contact between the central portion of the substrate 30 and the projections 22b, the area of contact between the central portion and the top plate 22 can be reduced. This means that inhibition of generation of particles can be expected. An annular portion of the substrate 30 surrounding the central portion of the substrate 30 contacts the second upper surface 22B. Because the entire annular portion contacts the second upper surface 22B, air in the gap 31 does not escape along the substrate 30 between the annular portion and the second upper surface 22B. The step of placing the substrate on the substrate support as described above is referred to as a mount step.

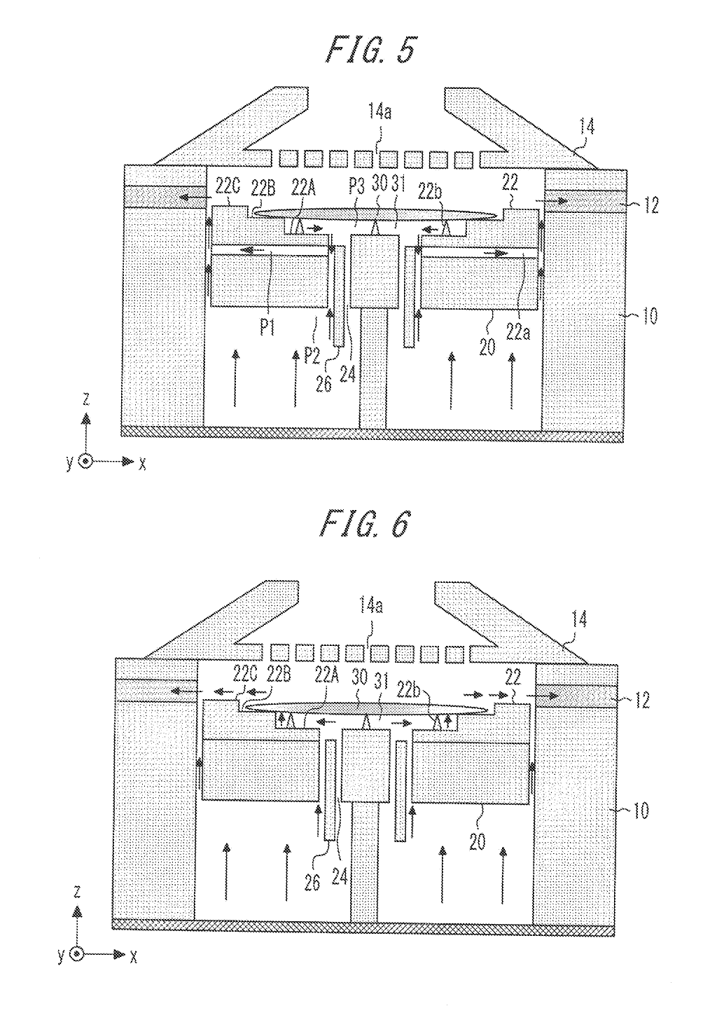

Subsequently, a gas is supplied to the substrate 30 from above the substrate 30 to process the substrate 30. FIG. 5 is diagram showing flows of the gas in the chamber 10 when the substrate is processed. The material gas passes through the slits 14a in the RF plate 14 to enter a plasma state and is supplied to the upper surface of the substrate 30. The material gas supplied to the upper surface of the substrate 30 and used for film forming on the substrate 30 is received by the exhaust duct 12 surrounding the substrate 30 and the substrate support to be discharged out of the chamber 10. The step of processing the substrate 30 as described above is referred to as a processing step.

In the processing step, an inert gas is supplied to a section below the susceptor 20. This inert gas may reach the gap 31 between the substrate 30 and the top plate 22 by passing through the first through holes 24, cause a gap between the substrate 30 and the second upper surface 22B, and reach the exhaust duct 12 from this gap. In such a case, there is a possibility of the material gas reaching the lower surface of the substrate 30 from the gap formed between the substrate 30 and the second upper surface 22B to form a film on the lower surface of the substrate 30. This mode will be referred to as a first lower surface film forming mode.

Further, the material gas moving into the section below the susceptor 20 by a roundabout way from the slits 14a may reach the lower surface of the substrate 30 by passing through the first through holes 24 to form a film on the lower surface of the substrate 30. This mode will be referred to as a second lower surface film forming mode. It is preferable to inhibit the first lower surface film forming mode and the second lower surface film forming mode as effectively as possible.

Use of the substrate processing apparatus according to the embodiment of the present invention enables inhibition of the first lower surface film forming mode and the second lower surface film forming mode. In the processing step according to the embodiment of the present invention, the gas in the gap 31 moves to the side surface of the substrate support by passing through the first through holes 24 and the second through holes 22a as indicated by arrows in FIG. 5. Consequently, the amount of gas supplied to the lower surface of the substrate 30 can be reduced.

In the following description, P1 represents the pressure in the second through hole 22a; P2, the pressure under the susceptor 20; and P3, the pressure in the gap 31. The inventor of the present invention thinks that it is ideal to realize P1<P2<P3 by providing the second through holes 22a. By setting P1 lower than P2 and P3, the gas under the susceptor 20 and the gas in the gap 31 can be discharged from the side surface of the substrate support via the second through holes 22a. By setting P2 smaller than P3, the supply of gas into the gap 31 can be limited.

The second through holes 22a function as pressure relief holes for the gas in the gap 31. The pressure in the gap 31 can thereby be maintained comparatively low, thus enabling prevention of forming of a gap between the substrate 30 and the second upper surface 22B. That is, the occurrence of the first lower surface film forming mode can be inhibited. Also, the gas in the gap 31 is enabled to escape from the gap 31 into the second through holes 22a. Therefore the second lower surface film forming mode can also be inhibited. Further, even in a case where particles are generated in the section below the susceptor 20, the particles cannot easily reach the lower surface of the substrate 30, because the gas in the gap 31 can be rapidly discharged from the gap 31 into the second through holes 22a. Thus, attachment of particles to the lower surface of the substrate 30 can be prevented.

In the processing step, it is preferable to realize the relationship P1<P2<P3, i.e., the relationship in which the pressure in the second through holes 22a is lower than the pressure under the substrate support, and in which the pressure under the substrate support is lower than the pressure in the gap 31.

If the second through holes 22a are made excessively large or excessively small, there is a possibility of failure to maintain the relationship P1<P2<P3. For example, when the second through holes 22a are made excessively large, a good result can be obtained in comparison with a case where no second through holes 22a are provided, but the effect of inhibiting film forming on the back surface of the substrate 30 is reduced in comparison with the case where the second through holes 22a are provided in the optimal way.

FIG. 6 is a sectional view of a substrate processing apparatus according to a comparative example. The substrate processing apparatus in the comparative example differs from the substrate processing apparatus according to the embodiment of the present invention in that no second through holes exist. In the comparative example, since no second through holes exist, gas concentrates in the gap 31 and the above-described first and second lower surface film forming modes occur.

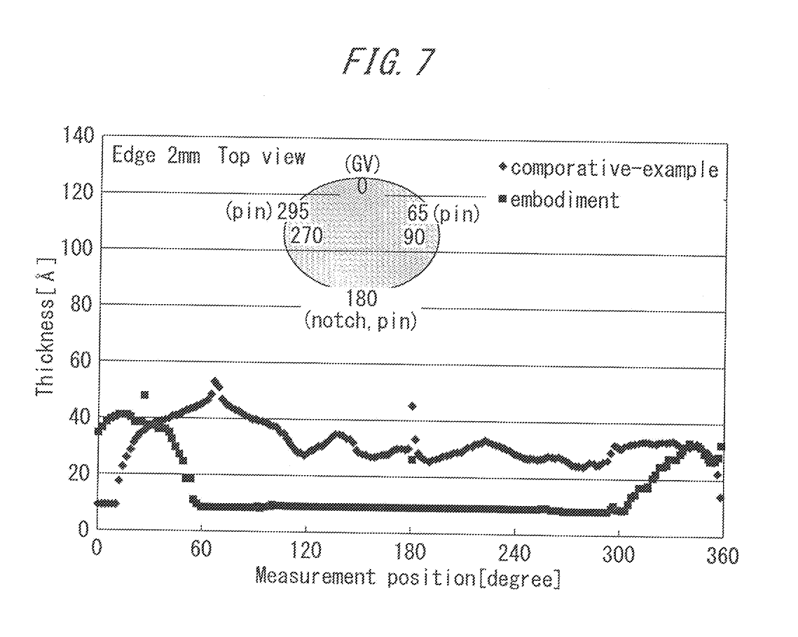

The substrate processing apparatus according to the embodiment of the present invention is capable of inhibiting the first and second lower surface film forming modes unlike the apparatus in the comparative example, since the second through holes 22a functioning as gas relief holes are formed. FIG. 7 is a diagram showing comparison between the state of film forming on the lower surface of a substrate in the method of manufacturing a semiconductor device according to the present invention and the corresponding state in the method according to the comparative example. More specifically, the film thickness on the wafer lower surface when AMZ film was formed to 13 nm on the wafer upper surface was measured. Measurements at 180 points on a portion at a distance of 2 mm from the wafer edge were made and plotted in a graph. In the substrate processing apparatus according to the present embodiment, in contrast to the comparative example, the film forming gas can be inhibited from moving to the lower surface of the substrate via the first through holes 24, since the second through holes 22a are formed. It can be understood from FIG. 7 that in the case of the present embodiment, film forming on the lower surface of the substrate occurred at about 65° and 298° at which the first through holes 24 are provided, but film forming on the lower surface of the substrate was prevented in a wide region.

The measurements results shown in FIG. 7 were quantitatively evaluated by defining an “area ratio”. The area ratio is given by the following expression:

area ratio=Σ 180-point peripheral film thickness (with second through)/Σ 180-point peripheral film thickness (without second through holes)

The area ratio is the value obtained by dividing the sum of the values of the film thickness at 180 points on a lower surface peripheral portion of a substrate processed with the substrate processing apparatus having the second through holes by the sum of the values of the film thickness at 180 points on the same lower surface peripheral portion of the same substrate processed with the substrate processing apparatus having no second through holes. The area ratio was 0.5. Thus, it was found that it was possible to reduce the thickness of the film formed on the lower surface of the substrate to about half that in the case of the comparative example by using the substrate processing apparatus according to the present embodiment.

In the substrate processing apparatus according to the present invention, there is no need to make any change in the susceptor 20 since the second through holes 22a are formed in the top plate 22. If the second through holes are formed in the susceptor 20, there is a need to take care not to cause interference between a heating wire in the susceptor 20 and the second through holes since a heater is embedded in the susceptor 20. However, the need to take such care can be eliminated by providing the second through holes 22a in the top plate 22. While it is preferable to provide the second through holes 22a in the top plate 22 as described above, the second through holes may be formed in the susceptor if there is no risk of interference with the heater.

The top plate 22 can be removed from the susceptor 20 for the purpose of cleaning the top plate 22. It is possible that after the interior of the chamber 10 is evacuated, the top plate 22 and the susceptor 20 adhere to each other and the top plate 22 cannot easily be removed from the susceptor 20. However, in the substrate processing apparatus according to the embodiment of the present invention, the adhesion between the top plate 22 and the susceptor 20 can be moderated because of the existence of the second through holes 22a that reduce the area of contact between the top plate 22 and the susceptor 20. Also, the provision of the second through holes 22a enables prevention of slippage of the substrate when the susceptor 20 is moved upward or downward.

The substrate processing apparatus and the method of manufacturing a semiconductor device according to the embodiment of the present invention can be variously modified within such a scope as not to lose their features. For example, while the substrate support is constituted of the susceptor 20 and the top plate 22 provided on the susceptor 20 and having the first and second upper surfaces, the substrate support may alternatively be formed of one member. Also, the number of the first through holes 24 and the number of second through holes 22a may be changed. Two or more second through holes 22a may be connected to one first through hole 24. The shape of the second through holes 22a can be changed to optimize the rate of gas flow in the second through holes 22a.

According to the present invention, film forming on the lower surface of the substrate can be prevented because the first through hole through which susceptor pin is passed and the second through hole connecting the first through hole and the side surface of the substrate support are provided in the substrate support.

Obviously many modifications and variations of the present invention are possible in the light of the above teachings. It is therefore to be understood that within the scope of the appended claims the invention may be practiced otherwise than as specifically described.

1. A substrate processing apparatus comprising:
a substrate support having a central first upper surface and a second upper surface surrounding the first upper surface and formed higher than the first upper surface;
an exhaust duct surrounding the substrate support, wherein a first through hole and a second through hole are formed in the substrate support, the first through hole being formed through the substrate support from the first upper surface, the second through hole connecting the first through hole and a side surface of the substrate support, and
a susceptor pin positioned in the first through hole to allow gas in a space above the first upper surface to be exhausted by travelling through the second through hole via the first through hole.

2. The substrate processing apparatus according to claim 1, wherein the substrate support has a susceptor and a top plate provided on the susceptor and having the first upper surface and the second upper surface, and
the second through hole is formed in the top plate.

3. The substrate processing apparatus according to claim 1, wherein the substrate support has a susceptor and a top plate provided on the susceptor and having the first upper surface and the second upper surface, and
the second through hole is formed between the top plate and the susceptor by forming a groove in a lower surface of the top plate.

4. The substrate processing apparatus according to claim 1, wherein a plurality of projections extending upward are formed on the first upper surface, and
the height of each upper end of the projections and the height of the second upper surface are generally equal to each other.

5. The substrate processing apparatus according to claim 1, wherein the susceptor pin is vertically movable in the first through hole.

6. A method of manufacturing a semiconductor device, comprising:
a mount step of placing a substrate on a substrate support having a central first upper surface and a second upper surface surrounding the first upper surface and formed higher than the first upper surface, the substrate being in contact with the second upper surface, a gap being provided between the substrate and the first upper surface; and
a processing step of processing the substrate by supplying a gas to the substrate from above the substrate,
wherein, in the processing step, the gas in the gap moves to a side surface of the substrate support by passing through a first through hole formed through the substrate support from the first upper surface and passing through a second through hole connecting the first through holes and the side surface of the substrate support.

7. The method of manufacturing a semiconductor device according to claim 6, wherein, in the processing step, the pressure in the second through hole is lower than the pressure under the substrate support, and the pressure under the substrate support is lower than the pressure in the gap.

8. The method of manufacturing a semiconductor device according to claim 6, wherein, in the processing step, the gas supplied to the upper surface of the substrate is discharged through an exhaust duct surrounding the substrate.

9. A substrate processing apparatus comprising:
a substrate support having a central first upper surface, a second upper surface surrounding the first upper surface and formed higher than the first upper surface, and a third upper surface surrounding the second upper surface and formed higher than the second upper surface; and
an exhaust duct surrounding the substrate support, wherein a first through hole and a second through hole are formed in the substrate support, the first through hole being formed through the substrate support from the first upper surface, the second through hole connecting the first through hole and a side surface of the substrate support, wherein
a gap is provided between the first upper surface and the substrate, and
the second upper surface directly contacts the substrate.
